(19) United States
(12) Patent Application Publication
(10) Pub. No.: US 2026/0047477 A1
(43) Pub. Date: Feb. 12, 2026

(54) PACKAGE FOR MULTI-SENSOR CHIP

(71) Applicant: Infineon Technologies AG, Neubiberg (DE)

(72) Inventors: Horst THEUSS, Wenzenbach (DE); Klaus ELIAN, Alteglofsheim (DE)

(21) Appl. No.: 19/275,460

(22) Filed: Jul. 21, 2025

(30) Foreign Application Priority Data
Aug. 12, 2024 (DE) 102024122922.5

(51) Int. Cl. H01L 23/31; G01D 11/24; G01D 21/02; H01L 21/56; H01L 23/00; H01L 25/04

(52) U.S. Cl. CPC H01L 23/3171; G01D 11/245; G01D 21/02; H01L 21/565; H01L 24/48; H01L 25/042; H01L 2224/48225

(57) ABSTRACT

An integrated sensor component includes a chip carrier and a first semiconductor chip and a second semiconductor chip, wherein either both semiconductor chips are arranged on the chip carrier or (alternatively) the second semiconductor chip is arranged on the chip carrier and the first semiconductor chip is arranged on the second semiconductor chip (chip-on-chip). The integrated sensor component further includes a first sensor element integrated in the first semiconductor chip and a second sensor element integrated in the second semiconductor chip, as well as a housing formed by a potting compound, which has an opening. Both the first sensor element and the second sensor element are located within the opening so that they can interact with the atmosphere surrounding the sensor component.

### CROSS-REFERENCE TO RELATED APPLICATION

This application claims priority to Germany Patent Application No. 102024122922.5 filed on Aug. 12, 2024, the content of which is incorporated by reference herein in its entirety.

### TECHNICAL FIELD

This description relates to a package (chip housing) for a semiconductor element with a plurality of integrated sensors.

### BACKGROUND

Nowadays, many sensor devices are configured as a so-called system-in package (SiP), e.g., they have a chip in a chip housing, in which both the sensor element and other electronic circuits are integrated. Many integrated sensors are so-called smart sensors (also referred to as intelligent sensors), which, in addition to the sensor element (which is sensitive to a certain environmental parameter such as pressure, temperature, carbon monoxide, or the like) also contain other electronic circuits, which, for example, process the sensor signal (e.g., amplify, digitize, filter, etc.) and can communicate with other electronic units if necessary.

Various concepts for the production of integrated sensors are known per se. One example is that of micromechanical structures integrated into silicon, so-called MEMS (microelectromechanical systems). A further example is sensor elements produced using SOI (silicon-on-insulator) or SOS (silicon-on-sapphire) technology, which contain e.g., piezoresistive elements. SiCOI (SiC-on-Insulator) technologies based on SiC (silicon carbide) are also known for producing integrated sensor elements for measuring pressure. In the following, sensor elements integrated into chips are referred to as sensor chips.

For example, MEMS sensors can be configured for a wide range of sensor applications. There are MEMS sensors for measuring pressure (in a gas atmosphere), for measuring air quality, for detecting various chemical elements, and much more. Properties of the medium surrounding the sensor are referred to below as environmental parameters. In order to measure an environmental parameter, the sensor element must be physically in contact with the surrounding medium. This means that the sensor chip, like other integrated circuits (ICs), must not be completely encapsulated in a potting compound, but must contain an opening that allows physical contact of the sensor element with the surrounding medium (usually a gas). The packaging of an integrated sensor therefore has to meet different requirements than the packaging of conventional semiconductor chips. In particular, with MEMS there is a risk of introducing mechanical stresses into the sensor chip, which can negatively affect the performance of the sensor chip. In the case of sensor components having a plurality of sensors, a space-saving arrangement may also be desirable.

### SUMMARY

Claim 1 relates to a sensor component having a plurality of integrated sensor chips. claim 10 relates to a method for producing a sensor component. Preferred example implementations and further developments are the subject matter of the dependent claims.

According to one implementation, the sensor component includes a chip carrier and a first semiconductor chip and a second semiconductor chip, wherein either both semiconductor chips are arranged on the chip carrier or (alternatively) the second semiconductor chip is arranged on the chip carrier and the first semiconductor chip is arranged on the second semiconductor chip (chip-on-chip). The sensor component further includes a first sensor element integrated in the first semiconductor chip and a second sensor element integrated in the second semiconductor chip, as well as a housing formed by a potting compound, which has an opening. Both the first sensor element and the second sensor element are located within the opening so that they can interact with the atmosphere surrounding the sensor component.

The production method includes, according to one example implementation, mounting a first semiconductor chip and a second semiconductor chip on a chip carrier or (alternatively) bonding the first semiconductor chip to the second semiconductor chip and mounting the second semiconductor chip (together with the first semiconductor chip) on the chip carrier, wherein a first sensor element is integrated in the first semiconductor chip and a second sensor element is integrated in the second semiconductor chip. The method further includes producing a chip housing from potting compound using a film-assisted-molding (FAM) process in such a way that an opening remains in the chip housing and the first sensor element and the second sensor element are located in the opening and can thus interact with the surrounding atmosphere of the semiconductor chips.

### BRIEF DESCRIPTION OF THE DRAWINGS

In the following, the implementation is explained in more detail using the examples shown in the illustrations. The representations are not necessarily to scale, and the example implementations shown are not restricted just to the represented aspects. Rather, emphasis is placed on presenting the principles underlying the example implementations. In the drawings:

FIG. 1 illustrates an example of a sensor component having a plurality of sensor chips arranged on a chip carrier.

FIG. 2 illustrates another example of a sensor component having a plurality of sensor chips arranged on a chip carrier.

FIGS. 3A-3D describe an example implementation of an improved method for producing a sensor component having a plurality of sensor chips arranged on a chip carrier, based on a series of cross-sectional representations.

FIG. 4 illustrates a variant of the example implementation from FIGS. 3A-3D.

FIG. 5 illustrates another example implementation of a sensor component with a plurality of sensor chips arranged on a chip carrier, based on a schematic plan view.

FIGS. 6 and 7 show modifications/variants of the example from FIG. 5.

FIG. 8 shows another example implementation in which a sensor chip is mounted on another chip using chip-on-chip assembly.

### DETAILED DESCRIPTION

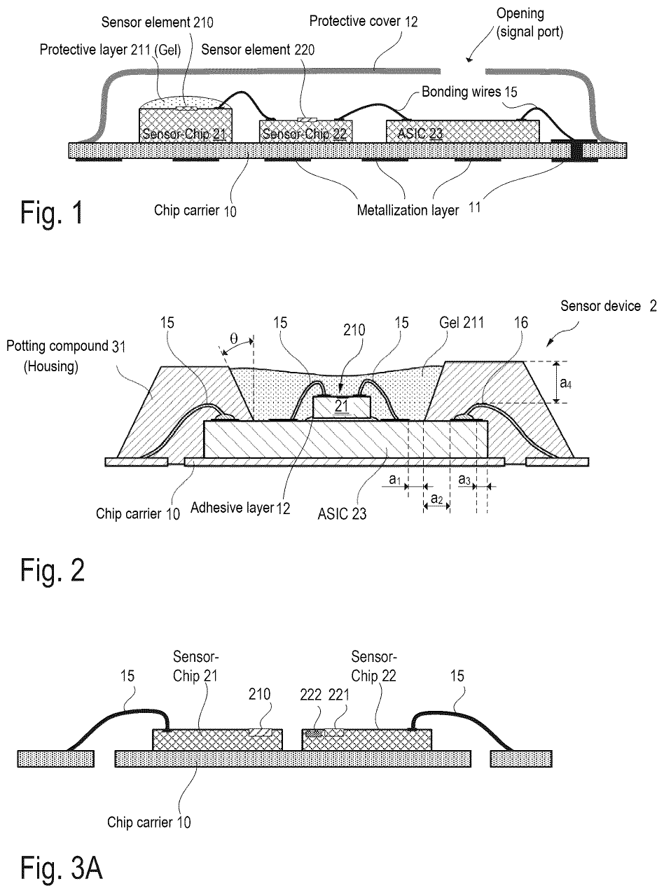

FIG. 1 illustrates a possible implementation of a sensor device having a plurality of sensor chips, which can measure different physical quantities. In the example shown, two sensor chips (sensor dies) 21 and 22 as well as another semiconductor chip (semiconductor die) 23 are arranged on a substrate (chip carrier 10). The chips may, for example, be mounted on a structured metallization layer of the chip carrier (e.g., by soldering). In the example shown the semiconductor chip 23 is, for example, an application-specific integrated circuit (ASIC), which are configured (inter alia) to process sensor signals from the sensor chips 21 and 22.

The sensor chip 21 has a sensor element 210 integrated into the chip, which is sensitive to pressure, for example. The sensor chip 22 has a sensor element 220, which may be sensitive to humidity, for example. In the example shown, the sensor element 210 is protected by a protective layer 211. The protective layer 211 is, for example, a protective gel, which is capable of transmitting the pressure of the surrounding atmosphere to the sensor element 210.

The chips 21, 22 and 23 are electrically contacted in a conventional manner using bonding wires 15. Corresponding bonding pads can be connected to the upper side of two chips using a bonding wire. Furthermore, bonding pads on the upper side of the chips can be connected to corresponding bonding pads on the chip carrier 10 (part of the metallization layer of the chip carrier 10) using bonding wires. In the example shown, the chip carrier has a metallization layer on both sides, wherein parts of the upper metallization layer can be connected to parts of the lower metallization layer 11 using vias. FIG. 1 is to be understood as a schematic sketch.

In particular, to protect the sensor chips 21 and 22 against environmental influences (such as dust particles), the chips on the upper side of the chip carrier are protected using a protective cover 12, which together with the chip carrier 10 forms a chip housing. The protective cover 12 has an opening 13, which allows the sensor chips 21 and 22 inside the housing to interact with the atmosphere of the environment.

As can be seen in FIG. 1, the protective cover 12 offers insufficient protection. The bonding wires 15 themselves are not protected. Such packaging concepts are therefore not suitable for a large number of applications where a higher degree of robustness is required.

FIG. 2 illustrates another example of an integrated sensor device 2, in which a sensor chip 21 is arranged chip-on-chip (CoC) on another chip 23. The chip 23 is, for example, a silicon-based semiconductor chip (e.g., an ASIC) and mounted in a known manner on a chip carrier 10. In the example shown, a lead frame can be used as a chip carrier. In certain variants, the chip carrier 10 can also be a multi-layer substrate. Chip-on-chip technology is a well-known technique by which one chip is mounted directly on another chip. Chip-on-chip technology is therefore different from other concepts, in which, for example, two or more chips are mounted side by side on a lead frame.

The sensor chip 21 has a sensor element 210 on the upper chip surface, which is configured to interact with the medium surrounding the chip (e.g., air or another gas) and thereby measure a property (e.g., a physical or chemical parameter) of the medium. This means that the sensor element 210 generates a signal that contains information about the property that is sought. As mentioned, the sensor element 210 can be a microelectromechanical system (MEMS). MEMS are known per se as sensor elements and are therefore not explained in detail here. For example, MEMS can be used to measure parameters such as the (static) pressure of the surrounding medium. Other MEMS sensor elements can measure, for example, a sound pressure or the presence of a substance (e.g., ozone, carbon monoxide, nitrogen dioxide, ammonia, etc.) or the concentration of a substance.

The whole of the underside surface of the sensor chip 21 is permanently connected to the underlying chip 23 (e.g., by soldering or adhesive bonding). The electrical connections between the sensor chip 21 and the underlying chip 23 are provided by bonding wires 15. These concepts are referred to as chip-to-chip bonding. The bonding wires connect corresponding contact surfaces (bonding pads) on the surfaces of the sensor chip 21 or the chip 23 underneath.

The semiconductor chip 23 is connected to the chip contacts (e.g., pins, solder balls, etc.) of the lead frame (chip carrier 30) using bonding wires 16. The chip 10 is encapsulated in a molding process with a potting compound 31 (molding compound). After curing, the potting compound 31 forms the chip housing (chip package), which only partially surrounds the chip 23 for sensor applications.

The potting compound 31 (the chip housing) has an opening (cavity) in the area in which the sensor chip 21 is situated. At this point it should be noted that during production, the chip 23 is first mounted on the chip carrier 10 (using a relatively soft adhesive layer), and then the electrical connections between the chip 23 and the lead frame are made using wire bonding (bonding wires 16). The chip housing 31 is then produced with the cavity.

For example, the chip housing is produced using film-assisted molding (FAM). This technology allows an almost pressureless encapsulation of sensitive microelectronic components with epoxy-containing molding compounds (e.g., potting compound 31). FAM and other suitable molding processes are known per se and are therefore not described in detail here.

Only once the chip housing has been produced can the sensor chip 21 be mounted within the cavity on the underlying semiconductor chip 23 and electrically contacted using the bonding wires 15. Depending on the application, the cavity can then remain open or be filled with a gel 211. For example, in the case of pressure sensors, the sensor element is often covered with a soft potting compound such as a gel (silicone gel). This soft potting compound must—even after curing—be soft enough to transfer the ambient pressure to the sensor element 210. The purpose of filling the cavity with a soft potting compound is to protect the underlying chip from (dirt) particles and corrosion. In the case of a chemical sensor (gas sensor) that detects the presence of a specific gaseous substance (e.g., carbon monoxide), the cavity must of course not be covered. Suitable softening compounds are significantly different from the molding compound (e.g., epoxy resin), which is used for producing the chip housing and which completely hardens (whereas the soft potting compound, like silicone gel, remains soft).

The sensor device 1 is relatively expensive to produce, in particular the chip-to-chip bonding (after producing the chip housing) and the separate wire bonding of the sensor chip increase the total cost of the sensor component. Certain geometry parameters must be observed for the potting process (e.g., FAM) for producing the chip housing. For example, minimum distances a₁ and a₂ must be maintained between the bonding pads arranged on the chip 23 and the side wall of the cavity (see FIG. 2). Furthermore, minimum distances a₃ and a₄ must be maintained between the chip edge of the chip 23 and the bonding pads and above the bonding wires 16 to the upper side of the housing. Even the side walls of the cavity cannot be produced as steep as desired, but require a certain minimum angle θ. An angle of θ=0 would correspond to a right angle between the chip surface and the sidewall of the cavity in the example shown. In view of given technology-related design parameters (e.g., a₁-a₄, θ), which must be adhered to, for multi-sensor systems (with a plurality of individual sensor chips) the concept shown in FIG. 2 is very complex and requires relatively large chip housings.

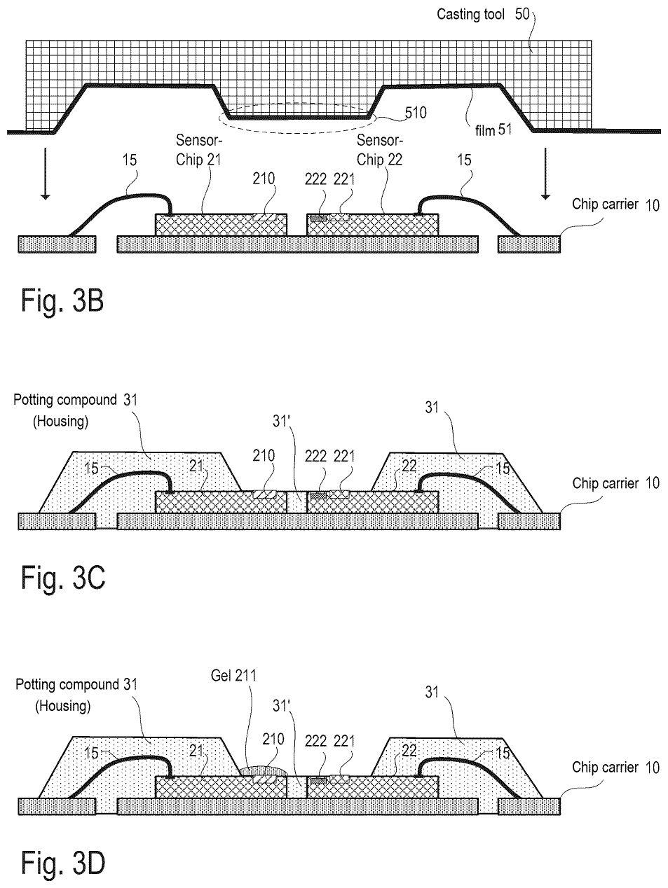

In the following, with reference to FIGS. 3A-3D, an example implementation of an improved method for producing a sensor device having a plurality of sensor chips is described.

In a first part of the method (see FIG. 3A), two or more sensor chips and optionally further chips are conventionally mounted on a chip carrier 10 (lead frame) and contacted using bonding wires 15. In the example shown, two sensor chips 21 and 22 are arranged on the lead frame. The sensitive regions of the sensor chips, e.g., the sensor elements, are arranged in an edge region of the sensor chips. In the example shown, the sensor element 210 is arranged in an edge region of the sensor chip 21, and the sensor elements 221 and 222 are arranged in an edge region of the sensor chip 22. The sensor elements are arranged in opposite edge regions of adjacent sensor chips. The sensor chips (or one of them) may also have application-specific circuits, for example, for processing and digitizing the sensor signals supplied by the sensor elements and/or one or more interfaces for communicating with other (external) circuits. The sensor elements 210, 221, 222 can measure various physical or chemical parameters. For example, the sensor element 210 is a pressure-sensitive sensor element, the sensor element 221 is a sensor element sensitive to humidity and the sensor element 22 is a temperature sensor element.

In the next part of the method (see FIG. 3B), the chips arranged on the chip carrier 10 are encapsulated in hard potting compound to produce the chip housing, wherein a single opening (cavity) is provided in the housing, which extends over the edge regions of (at least) two sensor chips so that the sensor elements are located in the opening of a plurality of sensor chips. Within the opening, the sensor chips (in particular the sensor elements integrated therein) are not covered by the potting compound, whereas the bonding wires 15 are completely encapsulated.

A FAM process—shown in FIG. 3B—can be used for producing the chip housing. In this case, a molding tool coated with a film 51 is used, wherein during the potting process a part 510 of the film directly touches and covers the surface of the sensor chips 21 and 22 (and the sensor elements 210, 221, 222); this ensures that the covered portion of the chip surface remains free and is not covered with potting compound 31. That is, the part 510 of the film 51 defines the aforementioned opening. FIG. 3C shows the sensor device after curing of the potting compound 31 which forms the chip housing. The region between two opposite side surfaces of adjacent chips is also filled with potting compound (see FIG. 3C, region 31′).

In the part of the method illustrated in FIG. 3D, one or more sensor elements are covered using a soft gel layer. In the example illustrated, the sensor element 210 of the chip 21 is protected by a layer 210 of silicone gel, whereas the other sensor elements 221 and 22 remain free.

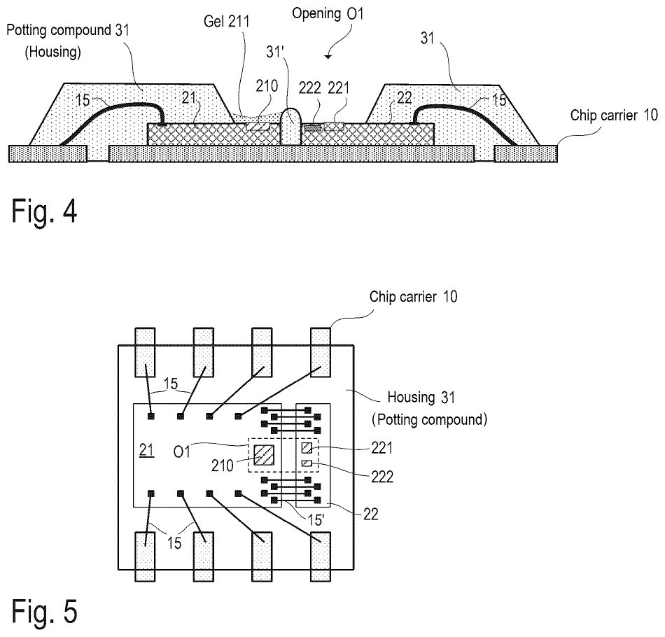

The example implementation shown in FIG. 4 is a modification of the example from FIG. 3D. While in the example of FIG. 3D the intermediate space between two adjacent chips is filled with potting compound 31′ up to the chip surface (e.g., the surface of the potting compound part 31′ is flush with the surface of the chips), in the variant shown in FIG. 4 the potting compound part 31′ projects beyond the chip surfaces between the two adjacent chips 21 and 22. The part 31′ projecting beyond the chip surface forms a kind of barrier that prevents the gel forming the gel layer 211 from flowing onto the adjacent chip 22. This somewhat simplifies the handling of the device during production.

FIG. 5 illustrates a variant of the example implementation from FIG. 3D using a schematic plan view. Two sensor chips 21 and 22 are mounted on a lead frame (chip carrier 10). One edge region of the sensor chip 21 comprises the sensor element 210 (in FIG. 5 on the right edge of the chip 21), and one edge region of the sensor chip 22 comprises the sensor elements 221 and 222 (in FIG. 5 on the left edge of the chip 22). For example, the sensor element 210 is used for pressure measurement, the sensor element 221 for air humidity measurement and the sensor element 222 for measuring a gas concentration such as CO₂.

The sensor chips 21 and 22 are electrically connected to each other using bonding wires 15′ (chip-to-chip bonding) and the sensor 21 is electrically connected using bonding wires 15 to corresponding chip contacts (e.g., solder pads) of the chip carrier 10. The chip housing is prepared as described above with reference to FIGS. 3A-3D (encapsulation of the chips in a potting compound 31), wherein the housing has an opening O1 (cavity), so that the sensor elements 210, 221, 222 can interact freely with the atmosphere surrounding the chip.

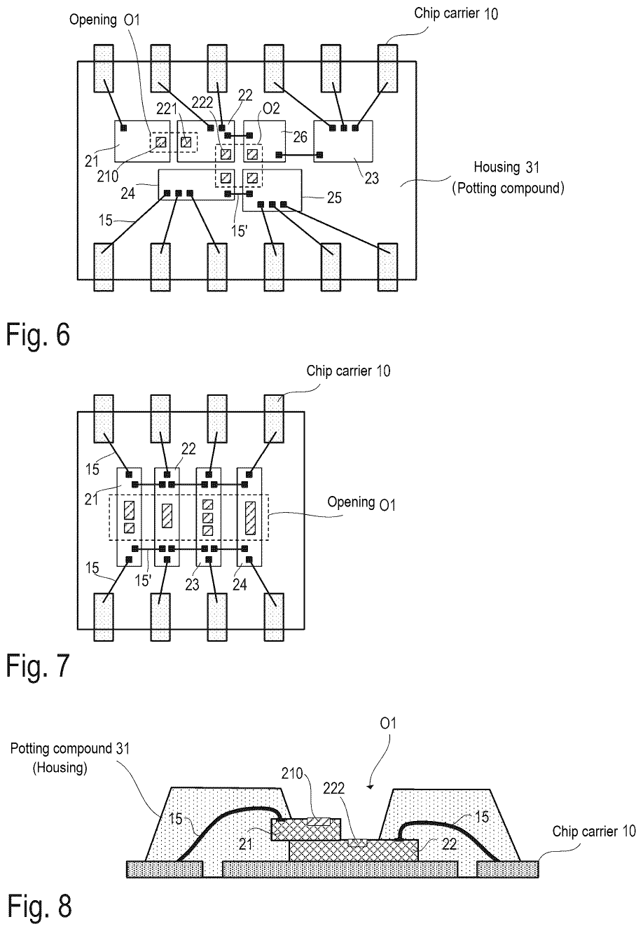

FIG. 6 illustrates a variant of the example from FIG. 5, wherein a total of six chips are arranged on a chip carrier and the chip housing has two openings/cavities. The sensor chips 21, 22, 24, 25 and 26 each have a sensor element (e.g., sensor elements 210 and 221), which are each shown as hatched rectangles. The sensor chip 22 has a second sensor element 222. The chip 23 can be an ASIC and, for example, preprocess the sensor signals of the other chips and transmit the information contained in the sensor signals to other circuits. The chips are connected to the chip contacts of the chip carrier 10 using bonding wires 15. The chip-to-chip bonding wires are labelled 15′ as in the previous example. Sensor elements 210 and 221 are situated within the opening O1. The sensor element 222 of the sensor chip 22 and the sensor elements of the chip 24, 25 and 26 are situated in the opening O2.

FIG. 7 illustrates another variant of the example of FIG. 5, wherein a single central opening extends over four substantially parallel arranged chips. In the example shown, the semiconductor chips (semiconductor dies) 21, 22, 23, and 24 have a relatively large aspect ratio (e.g., length/width>3). Each chip has one or more sensor elements (hatched in gray in FIG. 7).

The semiconductor chips are so narrow that the sensor elements are forced to be located close to the edge of the respective chips (along the long side in the edge region). The bonding wires are labelled as 15 and 15′, respectively, as in the previous examples.

FIG. 8 illustrates another example implementation which can be considered as a modification of the example from FIG. 3D. Unlike in the example from FIG. 3D, both sensor chips 21 and 22 are not mounted on the chip carrier 10, but only the chip 22 is mounted on the chip carrier, whereas the chip 21 is mounted on the chip 22 (chip-on-chip packaging). The sensor element 210 of the chip 21 can be electrically connected to the chip 22, for example, using so-called through-silicon vias. In the example shown, both chips are connected to corresponding chip contacts of the chip carrier 10 using bonding wires 15. The sensor element 210 of the sensor chip 21 is located in the edge region (near the right edge) of the chip. The sensor element 220 of the sensor chip 22 is located in a central surface region of the chip 22, however, close to the chip 21. Both sensor elements 210 and 222 are located in the (single) opening O1 of the chip housing, which can be produced, for example, using a FAM process (as described in relation to FIGS. 3A-3D).

The example implementations described here are summarized below. It is understood that the following is not a complete, but merely an example summary of technical features of the example implementations described here.

One example implementation relates to a sensor component which has the following: a chip carrier and a first semiconductor chip and a second semiconductor chip. The two semiconductor chips are arranged on the chip carrier (see e.g., FIGS. 3-7). Alternatively, the second semiconductor chip may be arranged on the chip carrier and the first semiconductor chip on the second semiconductor chip (chip-on-chip) (see FIG. 8). A first sensor element is integrated in the first semiconductor chip and a second sensor element is integrated in the second semiconductor chip. The sensor element further comprises a housing formed by a potting compound. The housing has an opening which is shaped so that both the first sensor element and the second sensor element are situated within the opening, so that the sensor elements can interact with the atmosphere surrounding the sensor component.

In one example implementation, the first and the second sensor element may be sensitive to different physical parameters. The following physical parameters can be considered: temperature, pressure, humidity, gas concentration of one or more gases or gas mixtures.

In one example implementation, the sensor element comprises bonding wires for electrically connecting the first semiconductor chip and/or the second semiconductor chip to corresponding chip contacts of the chip carrier, wherein the bonding wires are completely encapsulated in the potting compound. Other bonding wires can electrically connect the first semiconductor chip to the second semiconductor chip (chip-to-chip bonding, see e.g., FIG. 5-7)

In one example implementation, the upper sides of the first semiconductor chip and an upper side of the second semiconductor chip are partially covered with the potting compound. However, the sensor elements integrated in the semiconductor chips are exposed. The undersides of the semiconductor chips are connected to the chip carrier.

In one example implementation, an intermediate space between the first semiconductor chip and the second semiconductor chip is filled with potting compound. In this case, in particular in the region of the intermediate space between the semiconductor chips, the potting compound can project beyond the two semiconductor chips (see FIG. 4).

In one example implementation, the first sensor element and/or the second sensor element is covered with a gel layer (e.g., a silicone gel) and thus protected from negative environmental influences. In the example mentioned, in which a part of the potting compound projects beyond the upper side of the semiconductor chips, this part of the potting compound forms a kind of barrier that prevents the gel layer protecting a sensor element from flowing over to the adjacent semiconductor chip.

Further example implementations relate to a method for producing a sensor component having a plurality of sensor elements. In one example implementation, the method comprises mounting a first semiconductor chip and a second semiconductor chip on a chip carrier, wherein a first sensor element is integrated in the first semiconductor chip and a second sensor element is integrated in the second semiconductor chip. The method further comprises producing a chip housing from potting compound using a film-assisted-molding (FAM) process. The mold is configured so that an opening remains in the chip housing and the first sensor element and the second sensor element are located in the opening and can thus interact with the atmosphere surrounding the semiconductor chips.

In a further (optional) step, a gel layer can be applied to one (or both) of the semiconductor chips so that the gel layer covers the first sensor element and/or the second sensor element. The aforementioned barrier for the gel layer can be achieved by a suitable shaping of the mold. A possible wire bonding process will of course take place before the FAM process.

The example implementations described here are summarized below. It is understood that this is not a complete listing of technical features of the example implementations, but merely an example summary.

A first example implementation relates to a sensor component having a chip carrier and a first semiconductor chip and a second semiconductor chip, wherein either both semiconductor chips are arranged on the chip carrier (see FIG. 3D and FIGS. 4-7) or wherein (alternatively) the second semiconductor chip is arranged on the chip carrier and the first semiconductor chip is arranged on the second semiconductor chip (chip-on-chip, see FIG. 8). The sensor component further comprises a first sensor element integrated in the first semiconductor chip and a second sensor element integrated in the second semiconductor chip (see e.g., FIG. 4, sensor element 210 in the chip 21 and sensor element 222 in the chip 22), and a housing formed by a potting compound, which has an opening (cf. e.g., FIG. 4, opening O1). Both the first sensor element and the second sensor element are located within the opening so that they can interact with the atmosphere surrounding the sensor component.

According to one example implementation, the first sensor element and/or the second sensor element can (optionally) be covered with a gel layer (see FIG. 4, gel layer 211).

In some example implementations, the sensor device may comprise one or more bonding wires which electrically connect the first semiconductor chip to the second semiconductor chip (chip-to-chip bonding, see e.g., FIG. 5-7). In some example implementations, the sensor device may comprise bonding wires for electrically connecting the first semiconductor chip and/or the second semiconductor chip to corresponding chip contacts of the chip carrier. In both cases, the bonding wires can be completely surrounded by potting compound.

An upper side of the first semiconductor chip and an upper side of the second semiconductor chip may be partially covered with the potting compound (in particular, such that the bonding wires are protected and only the region around the sensor elements remains free, see e.g., FIGS. 3D and 4).

In some example implementations (see FIGS. 3D and 4-7), the first semiconductor chip and the second semiconductor chip (and optionally further semiconductor chips) are each mounted side by side on the chip carrier via their undersides. In this case, an intermediate space between the first semiconductor chip and the second semiconductor chip may also be filled with potting compound (see FIGS. 3D and 4, part 31′ of the potting compound). Optionally, in the region of the intermediate space between the first semiconductor chip and the second semiconductor chip, the potting compound can project beyond the two semiconductor chips (and form a mechanical barrier, see FIG. 4).

The first sensor element and the second sensor element may be in particular (but not necessarily) sensitive to different physical parameters (e.g., pressure, humidity, etc.).

Another example implementation relates to a production method for a sensor component. According to one example implementation the method comprises mounting a first semiconductor chip and a second semiconductor chip on a chip carrier, or (alternatively) bonding the first semiconductor chip to the second semiconductor chip and mounting the second semiconductor chip (together with the first semiconductor chip) on the chip carrier, wherein a first sensor element is integrated in the first semiconductor chip and a second sensor element is integrated in the second semiconductor chip. The method further comprises producing a chip housing from potting compound using a film-assisted-molding (FAM) process in such a way that an opening remains in the chip housing and the first sensor element and the second sensor element are located in the opening and can thus interact with the surrounding atmosphere of the semiconductor chips.

According to one example implementation, a mold used for the FAM process is formed in such a way that the potting compound projects beyond the two semiconductor chips in the region between the first semiconductor chip and the second semiconductor chip (see FIG. 4).

According to one example implementation, the method may comprise the application of a gel layer which covers the first sensor element and/or the second sensor element.

According to one example implementation, the method can—before producing the chip housing—further comprise the following: the production of bonding wire connections for electrically connecting the first semiconductor chip and/or the second semiconductor chip to corresponding chip contacts of the chip carrier, and/or the production of one or more bonding wire connections for electrically connecting the first semiconductor chip to the second semiconductor chip (chip-to-chip bonding).

### Aspects

The following provides an overview of some Aspects of the present disclosure:

Aspect 1: A sensor component, comprising: a chip carrier; a first semiconductor chip and a second semiconductor chip, wherein either both semiconductor chips are arranged on the chip carrier or the second semiconductor chip is arranged on the chip carrier and the first semiconductor chip is arranged on the second semiconductor chip; a first sensor element integrated in the first semiconductor chip and a second sensor element integrated in the second semiconductor chip; and a housing formed by a potting compound, which has an opening, wherein both the first sensor element and the second sensor element are located within the opening so that the first sensor element and the second sensor element interact with a surrounding atmosphere of the sensor component.

Aspect 2: The sensor component as recited in Aspect 1, wherein the first sensor element and the second sensor element are sensitive to different physical parameters.

Aspect 3: The sensor component as claimed in any of Aspects 1-2, further comprising: bonding wires for electrically connecting the first semiconductor chip and/or the second semiconductor chip to corresponding chip contacts of the chip carrier, wherein the bonding wires are completely surrounded by potting compound.

Aspect 4: The sensor component as claimed in any of Aspects 1-3, wherein an upper side of the first semiconductor chip and an upper side of the second semiconductor chip are partially covered with the potting compound.

Aspect 5: The sensor component as claimed in any of Aspects 1-4, wherein the first semiconductor chip and the second semiconductor chip are each mounted next to one another on the chip carrier via their undersides.

Aspect 6: The sensor component as recited in Aspect 5, wherein an intermediate space between the first semiconductor chip and the second semiconductor chip is filled with potting compound.

Aspect 7: The sensor component as recited in Aspect 6, wherein the potting compound projects beyond the first semiconductor chip and the second semiconductor chip in a region of the intermediate space between the first semiconductor chip and the second semiconductor chip.

Aspect 8: The sensor component as claimed in any of Aspects 1-7, wherein the first sensor element and/or the second sensor element is covered with a gel layer.

Aspect 9: The sensor component as claimed in any of Aspects 1-8, further comprising: one or more bonding wires, which electrically connect the first semiconductor chip to the second semiconductor chip.

Aspect 10: A method, comprising: mounting a first semiconductor chip and a second semiconductor chip on a chip carrier or bonding the first semiconductor chip to the second semiconductor chip and mounting the second semiconductor chip on the chip carrier, wherein a first sensor element is integrated in the first semiconductor chip and a second sensor element is integrated in the second semiconductor chip, producing a chip housing from potting compound using a film-assisted-molding (FAM) process in such a way that an opening remains in the chip housing and the first sensor element and the second sensor element are located in the opening and can thus interact with a surrounding atmosphere of the first semiconductor chip and the second semiconductor chip.

Aspect 11: The method as recited in Aspect 10, wherein a mold used for the FAM process is formed in such a way that the potting compound projects beyond the first semiconductor chip and the second semiconductor chip in a region between the first semiconductor chip and the second semiconductor chip.

Aspect 12: The method as recited in Aspect 11, further comprising: applying a gel layer which covers the first sensor element and/or the second sensor element.

Aspect 13: The method as claimed in any of Aspects 10-12, which, before producing the chip housing, further comprises: producing bonding wire connections for electrically connecting the first semiconductor chip and/or the second semiconductor chip to corresponding chip contacts of the chip carrier, and/or producing one or more bonding wire connections for electrically connecting the first semiconductor chip to the second semiconductor chip.

Aspect 14: A system configured to perform one or more operations recited in one or more of Aspects 1-13.

Aspect 15: An apparatus comprising means for performing one or more operations recited in one or more of Aspects 1-13.

1. A sensor component, comprising:
a chip carrier;
a first semiconductor chip and a second semiconductor chip, wherein either both semiconductor chips are arranged on the chip carrier or the second semiconductor chip is arranged on the chip carrier and the first semiconductor chip is arranged on the second semiconductor chip;
a first sensor element integrated in the first semiconductor chip and a second sensor element integrated in the second semiconductor chip; and
a housing formed by a potting compound, which has an opening,
wherein both the first sensor element and the second sensor element are located within the opening so that the first sensor element and the second sensor element interact with a surrounding atmosphere of the sensor component.

2. The sensor component as claimed in claim 1,
wherein the first sensor element and the second sensor element are sensitive to different physical parameters.

3. The sensor component as claimed in claim 1, further comprising:
bonding wires for electrically connecting the first semiconductor chip and/or the second semiconductor chip to corresponding chip contacts of the chip carrier, wherein the bonding wires are completely surrounded by potting compound.

4. The sensor component as claimed in claim 1,
wherein an upper side of the first semiconductor chip and an upper side of the second semiconductor chip are partially covered with the potting compound.

5. The sensor component as claimed in claim 1,
wherein the first semiconductor chip and the second semiconductor chip are each mounted next to one another on the chip carrier via their undersides.

6. The sensor component as claimed in claim 5,
wherein an intermediate space between the first semiconductor chip and the second semiconductor chip is filled with potting compound.

7. The sensor component as claimed in claim 6,
wherein the potting compound projects beyond the first semiconductor chip and the second semiconductor chip in a region of the intermediate space between the first semiconductor chip and the second semiconductor chip.

8. The sensor component as claimed in claim 1,
wherein the first sensor element and/or the second sensor element is covered with a gel layer.

9. The sensor component as claimed in claim 1, further comprising:
one or more bonding wires, which electrically connect the first semiconductor chip to the second semiconductor chip.

10. A method, comprising:
mounting a first semiconductor chip and a second semiconductor chip on a chip carrier or bonding the first semiconductor chip to the second semiconductor chip and mounting the second semiconductor chip on the chip carrier, wherein a first sensor element is integrated in the first semiconductor chip and a second sensor element is integrated in the second semiconductor chip,
producing a chip housing from potting compound using a film-assisted-molding (FAM) process in such a way that an opening remains in the chip housing and the first sensor element and the second sensor element are located in the opening and can thus interact with a surrounding atmosphere of the first semiconductor chip and the second semiconductor chips.

11. The method as claimed in claim 10,
wherein a mold used for the FAM process is formed in such a way that the potting compound projects beyond the first semiconductor chip and the second semiconductor chip in a region between the first semiconductor chip and the second semiconductor chip.

12. The method as claimed in claim 11, further comprising:
applying a gel layer which covers the first sensor element and/or the second sensor element.

13. The method as claimed in claim 10, which, before producing the chip housing, further comprises:
producing bonding wire connections for electrically connecting the first semiconductor chip and/or the second semiconductor chip to corresponding chip contacts of the chip carrier, and/or
producing one or more bonding wire connections for electrically connecting the first semiconductor chip to the second semiconductor chip.
